(19) United States
(12) Patent Application Publication
(10) Pub. No.: US 2004/0119492 A1
(43) Pub. Date: Jun. 24, 2004

(54) Method and apparatus for testing movement-sensitive substrates

(76) Inventors: Stefan Schneidewind, Reichenberg (DE); Claus Dietrich, Sacka (DE); Jorg Kiesewetter, Dresden (DE); Frank-Michael Werner, Dresden (DE)

Correspondence Address: BAKER & BOTTS, 30 ROCKEFELLER PLAZA, NEW YORK, NY, 10112

(21) Appl. No.: 10/699,121

(22) Filed: Oct. 31, 2003

(30) Foreign Application Priority Data
Nov. 1, 2002 (DE) 102 51 377.5
Dec. 12, 2002 (DE) 102 58 375.7

(51) Int. Cl. G01R 31/26

(52) U.S. Cl. 324/765

(57) ABSTRACT

The invention, which relates to a method for testing movement-sensitive substrates, in which a substrate is mounted on a chuck and makes contact with contact-making needles, and relates to an apparatus which is provided with a chuck which is connected to a positioning apparatus and has contact needles, is based on the object of allowing testing of physical characteristics relating to the mechanical dynamic response of movement-sensitive substrates. This object is achieved in that the substrate is mechanically accelerated during the determination of the physical characteristics. The chuck in this case comprises a lower chuck member and an upper chuck member, with the two chuck members are arranged to move relative to one another, and with at least one movement element being arranged between the two chuck members.

### BACKGROUND OF THE INVENTION

The invention relates to a method for testing substrates having circuits sensitive to mechanical movement in which a substrate is mounted on a chuck and makes contact with contact needles, and the contact needles are then used to determine physical characteristics of the substrate.

The invention also relates to an apparatus for testing having circuits sensitive to mechanical movement substrates having a chuck which is provided with a substrate holding surface, having a positioning apparatus which is connected to the chuck, and having contact needles.

Movement-sensitive semiconductor circuit components are used in various fields of application, for example in motor vehicle positioning and airbag systems. These movement-sensitive semiconductor components are used, for example, to measure acceleration of a linear or rotational type acting on the component. Like other semiconductor components, these movement-sensitive semiconductor components have to be tested during the production process.

Appropriate test apparatus, so-called probers, are provided for testing or checking semiconductor components. The semiconductor components can be tested on these probers in various production phases, for example, while still in the semiconductor wafer or as separated components. The semiconductor components may be in the form of discs with an upper face and with a lower face parallel to it, and with a height which corresponds to the thickness of the semiconductor wafer.

For the probers, the semiconductor components represent substrates which are held firmly on a clamping apparatus of the prober, called a chuck. In order to test the substrates, contact needles make contact with suitable measurement points on the substrate, and these contact needles are used to determine the physical characteristics, in particular the electrical characteristics, of the circuits on the substrates.

Conventional probers according to the prior art can be used to test only the static mechanical behavior of movement-sensitive circuits of the type mentioned initially. One disadvantage in this case is that the mechanical-dynamic response cannot be tested.

The invention is thus based on the object of allowing testing of physical characteristics relating to the mechanical-dynamic response of the movement-sensitive substrates.

### SUMMARY OF THE INVENTION

According to the invention, the object is achieved with regard to the method by the substrate being mechanically accelerated during the determination of physical characteristics.

An acceleration allows testing of the substrate and of mechanical-dynamic conditions, thus taking into account the subsequent practical use during testing itself.

One preferred variant of the method provides for the substrate to be subjected to an acceleration which is initially positive and is then negative down to the stationary state. This makes it possible to move the substrate through a short deflection.

One possible way to simulate the movement of the substrate is for the acceleration to represent a linear acceleration. This makes it possible to provide linear acceleration in a direction which is parallel to the upper face of the substrate. Another possibility is for the linear acceleration to be in a direction perpendicular to the upper face of the substrate.

Another possible way to simulate the movement of the substrate is for the acceleration to represent a rotary acceleration about a rotation axis which perpendicular to the upper face.

The two simulation options can also be superimposed on one another. The chosen simulation option will depend on the functional principle and the operational purpose to be tested.

It is expedient for the acceleration to be repeated. In particular, it is expedient for the substrate to be caused to oscillate mechanically. An oscillation can be provided easily and allows testing with very high accelerations and small deflections, which has a positive influence on the contact-making process.

The method according to the invention can also be carried out in such a way that the acceleration is produced by a mechanical blow. In this case, an acceleration is applied to the substrate in the form of a dirac impulse. This allows the reaction of the substrate both to the accelerating flank and to the decelerating flank to be measured. Assuming that the dirac impulse does not have an ideal form, that is to say that there is a time period between the two flanks, it is also possible to carry out the measurement on either one flank or on the other flank of the sudden acceleration or deceleration.

With regard to the apparatus, the objective according to the invention is achieved in that the chuck comprises a lower chuck member, which is connected to the positioning apparatus, and an upper chuck member, which is provided with the substrate holding surface. The two chuck members are connected to one another such that they can move relative to one another, and at least one movement element is arranged between the upper chuck member and the lower chuck member. This allows the chuck to still be operated in the normal way, by means of which the substrate can be positioned relative to the contact needles by means of the positioning device. The acceleration which is required for mechanical/dynamic testing can then be introduced into the substrate without any change to the configuration of a prober.

In order to initiate a linear acceleration in the vertical direction, it is expedient for the lower face of the upper chuck member and the upper face of the lower chuck member to be at a distance from one another forming an intermediate space, and for at least one movement element, which can move in a direction at right angles to the upper face of the substrate, to be arranged in the intermediate space. The upper chuck member then rests on the movement element. The upper chuck member is moved relative to the lower chuck member by a movement or expansion of the movement element. When one movement element or two movement elements is or are used, a guide should preferably be provided between the upper chuck member and the lower chuck member.

With three movement elements, as there are in one preferred embodiment of the invention, there is no need for an additional guide since the movement elements themselves form a three-point contact, so that there is no need for stabilizing via a guide.

In order to prevent the upper chuck member from jumping during acceleration, the invention provides for the upper chuck member and the lower chuck member to be connected to one another loaded by spring force and separated by the movement elements. This makes it possible to prevent the upper chuck member from lifting off the movement elements.

One embodiment relating to this provides for a tensioning pin to be mounted in the upper chuck member, with the tensioning pin projecting from the lower face of the upper chuck member through an aperture in the lower chuck member as far as the lower face of the lower chuck member. At its end under the lower face of the lower chuck member, this tensioning pin has a spring stop, between which and the lower face of the lower chuck member a spring is clamped.

In order to initiate a linear acceleration in the horizontal direction, provision is made for the upper chuck member to be mounted on the lower chuck member such that it can move in a direction parallel to the upper face of the substrate. At least one elongated movement element is arranged in the intermediate space between the lower face of the upper chuck member and the upper face of the lower chuck member and is attached at one end to the lower chuck member, and at the other end to the upper chuck member. The movement element then introduces the acceleration into the upper chuck element by movement or expansion.

In order to initiate a rotational acceleration, provision is made for the upper chuck member to be mounted on the lower chuck member such that it can rotate about a rotation axis at right angles to the upper face. At least one elongated movement element is arranged in the intermediate space between the lower face of the upper chuck member and the upper face of the lower chuck member and is attached at one end to the lower chuck member, and is attached to the other end to the upper chuck member at a lateral distance from the rotation axis.

In this case, it is possible for the rotation axis to be in the form of a virtual rotation axis. In this case, provision is made for two or more movement elements to be arranged, whose torques about the rotation axis are in equilibrium with respect to one another. The torque equilibrium ensures that the upper chuck element rotates about the virtual rotation axis, and is not moved linearly.

One particularly preferred embodiment provides for the movement elements to be in the form of piezoceramic components, which are electrically conductively connected to drive electronics. Piezoceramic components change their geometric dimensions in accordance with an applied voltage by means of a change in the crystal lattice. The geometric change is admittedly in the region of or less than one millimeter, but can take place very quickly, for which reason very high accelerations can be achieved in an expedient manner.

On the one hand, relative movements between the substrate and the contact needles are possible and this can be achieved, in particular, by means of a special configuration of the contact needles. On the other hand, however, relative movements between the substrate and the contact needles can be prevented in that the contact needles are at least indirectly mechanically connected to the upper chuck member such that they can move. The needles are then likewise accelerated together with the upper chuck member, and thus follow the movement of the upper chuck member. In consequence, there is therefore no need for the special configuration of the contact needles while, on the other hand, greater movement distances are possible without the contact needles “scratching” on the substrate.

One embodiment in this case provides for the contact needles to be arranged on a needle card, and for the needle card to be mechanically connected to the upper chuck member. In this case, the needle card takes over the introduction of the movement to the contact needles.

Another embodiment relating to this is characterized in that the contact needles are provided with needle holders, and in that a needle holder plate, on which the needle holders can be connected, is connected to the upper chuck member. In this case, acceleration of the upper chuck member towards the needles is guided by the needle holder plate, and the needle holders are guided to the contact needles.

### BRIEF DESCRIPTION OF THE DRAWINGS

The invention will be explained in more detail in the following text with reference to an exemplary embodiment. In the associated drawings:

FIG. 1 shows a side view of a chuck for vertical acceleration,

FIG. 2 shows a side view of a chuck for vertical acceleration with spring prestressing,

FIG. 3 shows a side view of a chuck for rotational acceleration.

FIG. 4 shows a section illustration along the line IV-IV in FIG. 3.

### DESCRIPTION OF THE INVENTION

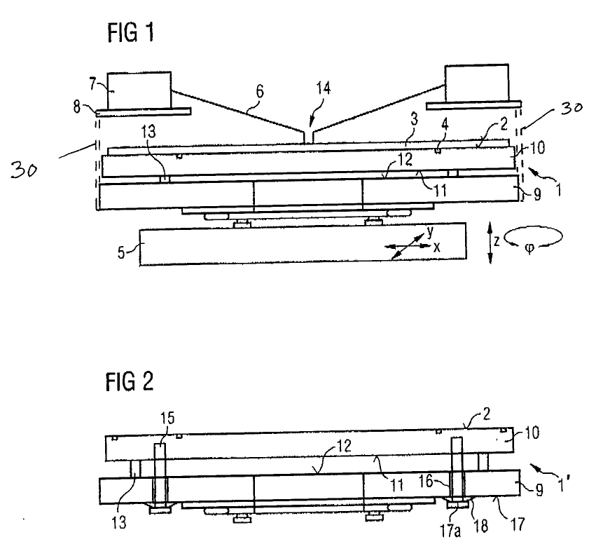

An apparatus according to the invention for testing movement-sensitive substrates is provided with a chuck 1, as is illustrated in FIG. 1. This chuck 1 is provided with a substrate holding surface 2. A semiconductor wafer 3 can be placed on this substrate holding surface. This semiconductor wafer 3 is held by a vacuum between the lower face of the semiconductor wafer 3 and the substrate holding surface 2. This vacuum is introduced via vacuum guide channels 4.

The chuck 1 is connected to a positioning apparatus 5, which can position the chuck 1 in X-Y plane parallel to the substrate holding surface 2, in a Z direction at right angles to the substrate holding surface 2, and about a rotation angle. The semiconductor wafer 3 contains movement-sensitive substrates in the form of acceleration-measuring components, so-called accelerometers. For testing, these substrates make contact with contact needles 6, and the physical characteristics of the substrates are determined via these contact needles 6. These contact needles are held by probe holders 7, which are themselves supported and are mounted on a probe holder plate or needle card 8. In an optional arrangement the plate or needle card can be connected to the chuck by support members 30. The chuck 1 is formed from two members and comprises a lower chuck member 9 and an upper chuck member 10. In this case, the lower chuck member 9 is connected to the positioning apparatus 5. The upper chuck member 10 is provided with the substrate holding surface 2. The two chuck members 9 and 10 can move relative to one another. Movement elements 13 in the form of piezoceramic components are arranged between the lower face 11 of the upper chuck member 10 and the upper face 12 of the lower chuck member 9. The movement elements 13 produce a gap between the lower face 11 and the upper face 12, thus forming an intermediate space. The three movement elements form a secure three-point contact for the upper chuck member 10 on the lower chuck member 9.

The piezoceramic components which are in the form of movement elements 13 are electrically conductively connected in a manner which is not illustrated in any more detail to drive electronics. These drive electronics can apply a voltage to the piezoceramic components. Depending on the magnitude of the voltage, the piezoceramic components expand via their crystal lattice structure and, while this expansion is being formed, ensure that an acceleration is introduced into the upper chuck member 10 and, via it, into the substrate 14 as well.

In general, a piezoceramic component expands to an extent which is proportional to the applied voltage. The acceleration of the substrate 14 that is of interest for producing movement may be calculated, as described in the following text. For sinusoidal excitation, known theory can be used to calculate the deflection s, the velocity v and the acceleration a as a function of the time t and of the frequency f as follows:

s(t)=s₀·sin (2πf·t)

v(t)=s₀·2πf·cos (2πf·f)

a(t)=−s₀·Δπ²f²·sin (2πf·t)

aₚₑₐₖ=Δπ²f²s₀

a_{RMS}=\sqrt{2}π²f²s₀

$${s}_{0} = \frac{{a}_{R M S}}{2 \sqrt{2} \cdot {π}^{2} {f}^{2}}$$

As can be seen from this, the acceleration increases with the square of the frequency for a constant deflection amplitude. For this reason, high accelerations can in fact be achieved with small deflection amplitudes. On the other hand, only low accelerations can actually be achieved at low frequencies.

At 1 kHz, a deflection amplitude of 0.36 μm is required in order to achieve a root mean square (RMS-) acceleration of 1 g (1 g=9.82 m/s²). In consequence, 1.8 μm is required for an effective 5 g acceleration. At 500 Hz, 7 μm is required for this purpose. A root mean square acceleration of 1 g at 10 Hz would require a deflection of 3.6 mm, which is not feasible with stationary contact needles and would lead to the needles being broken. For this reason, higher frequencies are preferred when using piezoceramic components.

The acceleration which can be achieved using piezoceramic components can be calculated from the frequency f, from the applied AC voltage with a peak voltage U_{AC-peak} (without any superimposed DC voltage) and from the maximum deflection sₘₐₓ which is achieved for a maximum of a voltage U_{DC-max} that is permissible for the piezoceramic component. The result is converted from SI units to g by division by 9.82 m/gs², and is converted to a root mean square value (RMS), which is of relevance here, by dividing by \sqrt{2}:

$$\begin{matrix}{s}_{0} = {s}_{max} \cdot \frac{{U}_{A C - Peak}}{{U}_{D C - max}} \\ {a}_{R MS} = \frac{2 \sqrt{2} {π}^{2} {f}^{2} {U}_{A C - peak} {s}_{max}}{9.82 \frac{m}{{s}^{2} g} {U}_{D C - max}}\end{matrix}$$

The acceleration which is required for testing the substrate 14 can thus be set exactly via the voltage which is applied to the piezoceramic component.

Particularly in the case of high accelerations, it is possible with a chuck 1 as shown in FIG. 1 for the upper chuck member to be briefly detached from the movement elements 13 or from the lower chuck member 9, and thus to jump. A chuck 1′ as illustrated in FIG. 2 is provided in order to prevent such jumping. Chuck 1′ is used in the same way as illustrated in FIG. 1. In the case of the Chuck 1′ illustrated in FIG. 2, tensioning pins 15 are mounted in the upper chuck member 10. These tensioning pins 15 project through an aperture 16 in the lower chuck member 9. Spring stops 17a are provided at the lower ends of the tensioning pins 15, which project as far as below the lower face 17 of the lower member 9, and springs 18 are clamped between the spring stops 17a and the lower face 17 of the lower chuck member 9. As is illustrated in FIG. 2, the springs 18 are in the form of plate springs.

The tensioning pin 15 now spring-loads the upper chuck member 10, drawing it in the direction of the lower chuck member 9. In the process, the distance which is produced via the movement elements 13 between the upper chuck member and the lower chuck member 9 is maintained, and the movement elements 13 are clamped between the two members. This means that the upper chuck member 10 does not jump when high accelerations are introduced into it by means of the movement elements 13.

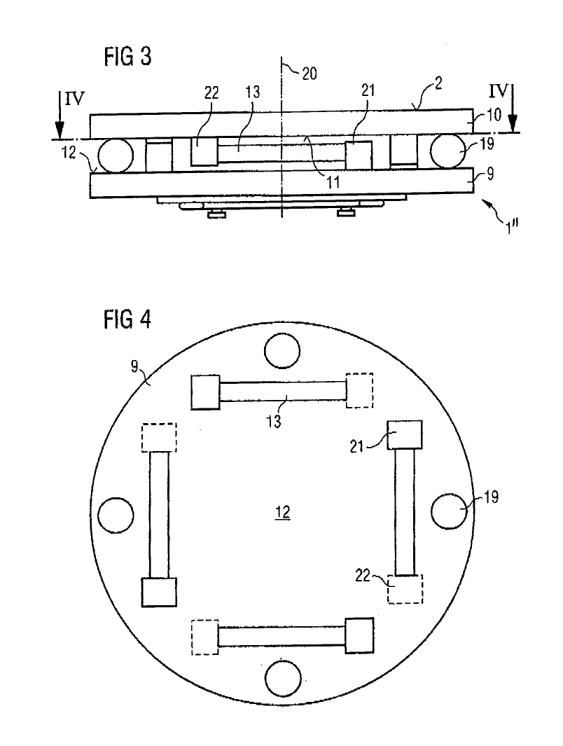

FIG. 3 and FIG. 4 illustrated a chuck 1 which can be used installed in the same way as illustrated in FIG. 1. The Chuck 1″ as shown in FIG. 3 and FIG. 4 is used to produce a rotational movement or a rotary acceleration, which acts on the semiconductor wafer 3, and thus on the substrate 14. For this purpose, the upper chuck member 10 is mounted on the lower chuck member 9 via balls 19 such that it can rotate about a virtual rotation axis 20. In this case, the distance between the upper chuck member 9 and the lower chuck member 10 is set via the balls 19. Four elongated movement elements 13, arranged in the intermediate space that is formed in this way, are arranged along the lower face 11 of the upper chuck member 10 and along the upper face 12 of the lower chuck member 9, and are all at the same lateral distance from the rotation axis 20. Each movement element 13 is attached at a first end 21 to the lower chuck member 9 and at a second end 22 to the upper chuck member 10. Since the distance between the movement elements 13 and the virtual rotation axis 20 is the same, there is a torque equilibrium on the rotation axis 20, so that although the upper chuck member is rotated with respect to the lower chuck member when the movement elements 13 are energized, it is not, however, moved linearly. In this case, the movement elements 13 (which are in this case likewise in the form of piezoceramic components) are in each case excited via the same excitation voltage at the same excitation frequency.

Linear acceleration in the X-Y plane can be provided in a simple manner with this arrangement by driving each of the mutually opposite movement elements 13 in opposite directions, that is to say, when one movement element 13 expands, the opposite movement element 13 contracts by the same amount, thus resulting in a linear movement in the longitudinal extent of these movement elements 13.

Superimpositions of linear and rotational movements are thus also possible.

The movements of the substrate 14 relative to the contact needles 6 are compensated for by the contact needles 6 being designed to be elastic. This elasticity may, for example, be achieved by means of very long and thin contact needles 6.

Further movement compensation can be achieved by a modification of the contact-pressure force of the contact needles 6 on the substrate 14. In this case, it is possible either to set the contact force such that the contact needle 6 slides on the contact surface, or to set it such that sliding is just avoided, and all the movement is absorbed via the contact needles 6. The corresponding setting depends on the application and on the nature of the substrates.

While there have been described what are believed to be the preferred embodiments of the invention, those skilled in the art will recognize that other and further changes and modifications may be made thereto without departing from the spirit of the invention, and it is intended to claim all such changes and modifications as fall within the true scope of the invention.

We claim:

1. In a method for testing semiconductor substrates, wherein a substrate is mounted on a chuck and makes contact with contact needles, said contact needles being connected to enable testing of electrical characteristics of circuit elements on said semiconductor substrate, the improvement wherein said substrate is subjected to acceleration during testing of said electrical characteristics.

2. A method as specified in claim 1 wherein the substrate is subjected to acceleration which is initially positive and is then negative down to the stationary state.

3. A method as specified in claim 1 wherein the acceleration comprises a linear acceleration.

4. A method as specified in claim 3 wherein the linear acceleration takes place in a direction which is parallel to the upper face of the substrate.

5. A method as specified in claim 3 wherein the linear acceleration takes place in a direction which is perpendicular to the upper face of the substrate.

6. A method as specified in claim 1 wherein the acceleration represents a rotary acceleration with respect to a rotation axis which is perpendicular to an upper face of the substrate.

7. A method as specified in claim 2 wherein the acceleration is repeated.

8. A method as specified in claim 7 wherein the substrate is caused to oscillate mechanically.

9. A method as specified in claim 2 wherein the acceleration is produced by a mechanical blow.

10. Apparatus for testing substrates having circuits sensitive to mechanical movement, comprising a chuck having an upper chuck member for holding said substrate, a lower chuck member, connected to a positioning apparatus, and motion producing apparatus interconnecting said upper and lower chuck members for providing relative movement between said members during testing of substrates.

11. Apparatus as specified in claim 10 wherein a lower face of the upper chuck member and an upper face of the lower chuck member are at a distance from one another, forming an intermediate space, and wherein at least one movement element is arranged in the intermediate space and provides motion in a direction perpendicular to an upper face of the substrate.

12. Apparatus as specified in claim 11 wherein three movement elements are provided.

13. Apparatus as specified in claim 11 wherein the upper chuck member and the lower chuck member are connected to one another loaded by spring force and separated by at least one movement element.

14. Apparatus as specified in claim 13 wherein a tensioning pin is mounted on the upper chuck member, projects from a lower face of the upper chuck member through an aperture in the lower chuck member as far as the lower face of the lower chuck member and has a spring stop at its end under the lower face of the lower chuck member, and wherein a spring is clamped between the spring stop and the lower face of the lower chuck member.

15. Apparatus as specified in claim 10 wherein the upper chuck member is mounted on the lower chuck member in a manner that allows movement in a direction parallel to an upper face of a substrate, and wherein at least one elongated movement element is arranged in an intermediate space along a lower face of the upper chuck member and along an upper face of the lower chuck member, and wherein said movement member is attached at one end to the lower chuck member and at the other end to the upper chuck member.

16. Apparatus as specified in claim 10 wherein the upper chuck member is mounted on the lower chuck member in a manner that allows rotation such that it can rotate about a rotation axis which is perpendicular to an upper face of a substrate wherein at least one elongated movement element is arranged in an intermediate space along a lower face of the upper chuck member and along an upper face of the lower chuck member, said movement element being attached at one end to the lower chuck member, and at the other end to the upper chuck member at a lateral distance from the rotation axis.

17. Apparatus as specified in claim 10 wherein the rotation axis is a virtual rotation axis, and wherein two or more movement elements are arranged between said upper chuck member and said lower chuck member, said movement elements providing torques about the rotation axis in equilibrium with respect to one another.

18. Apparatus as specified in claim 10 wherein the movement elements are in the form of piezoceramic components, which are arranged for connection to a driving circuit.

19. Apparatus as specified in claim 10 wherein contact needles are mechanically connected to the upper chuck member for movement therewith.

20. Apparatus as specified in claim 19 wherein the contact needles are arranged on a needle card, and the needle card is mechanically connected to the upper chuck member.

21. Apparatus as specified in claim 19 wherein the contact needles are provided with needle holders, and wherein a needle holder plate, on which the needle holders can be mounted, is connected to the upper chuck member.
